(19) United States
(12) Patent Application Publication
(10) Pub. No.: US 2026/0015234 A1
(43) Pub. Date: Jan. 15, 2026

(54) BORON-NITRIDE NANOTUBES (BNNT) FOR LOW-K DIELECTRICS SPACERS AND FASTER INTERCONNECTS

(71) Applicant: SAMSUNG ELECTRONICS CO., LTD., Suwon-si (KR)

(72) Inventors: Nikhil SIVADAS, Boston, MA (US); Yongwoo SHIN, Concord, MA (US); Ali HAMZE, Dorchester, MA (US)

(73) Assignee: SAMSUNG ELECTRONICS CO., LTD., Suwon-si (KR)

(21) Appl. No.: 18/924,499

(22) Filed: Oct. 23, 2024

Related U.S. Application Data
(60) Provisional application No. 63/669,391, filed on Jul. 10, 2024.

(51) Int. Cl. C01B 21/064; H01L 23/522; H01L 23/532; H01L 29/06; H01L 29/423; H01L 29/49; H01L 29/775; H01L 29/786

(52) U.S. Cl. CPC C01B 21/064; H01L 23/5226; H01L 23/5329; H10D 30/43; H10D 30/6735; H10D 30/6739; H10D 30/6757; H10D 62/121; C01P 2004/133; C01P 2006/40

(57) ABSTRACT

A structure includes boron nitride nanotubes, wherein the structure (i) is an extension region in a field-effect transistor or (ii) comprises a metallic interconnect to reduce the dielectric constant and therefore the RC-delay in the device. Also, a field-effect transistor structure includes a low-k spacer layer between metallic interconnects, wherein the low-k spacer layer includes boron nitride nanotubes. In addition, a method for reducing RC delay in an integrated circuit includes forming a component of the integrated circuit from boron nitride nanotubes.

### CROSS-REFERENCE TO RELATED APPLICATION

This application is based on and claims priority from U.S. Provisional Application No. 63/669,391 filed on Jul. 10, 2024 in the U.S. Patent and Trademark Office, the disclosure of which is incorporated herein by reference in its entirety.

### BACKGROUND

### 1. Field

Embodiments relate to a structure including boron nitride nanotubes, wherein the structure (i) is an extension region in a field-effect transistor or (ii) comprises a metallic interconnect to reduce the dielectric constant and therefore the resistive-capacitive (RC) delay in the device.

### 2. Description of the Related Art

As transistor size decreases, operation speed increases. However, delays in interconnects (RC delay) are limiting the speed of signals. The relationship of transistor operation speed and interconnect delays is shown in FIG. 1.

In particular, shrinking the cross-section of a wire increases its resistance, and bringing wires closer together increases capacitance between the wires. As a result, RC delay increases as device size decreases.

One solution is to use low-k spacers between metals to minimize RC delay (see FIG. 2, showing Cu with low-k spacers). In this disclosure, low-k is defined as k<4.

One of the current bottlenecks for faster transistor performance is the lack of availability of suitable low-dielectric (low-k) materials. Current choices have structural issues (porous, allowing ionic diffusion) and have a dielectric constant ˜2.4.

Identifying candidates with a lower dielectric constant that are structurally stable can lead to significant improvement to transistor speed.

Current state-of-the-art technology is porous-SiCOH (k=2.4), which reduces the dielectric constant relative to SiCOH (k=2.8) by introducing pores. However, this comes at the cost of structural stability, and increasing likelihood of dielectric breakdown and ionic diffusion through the dielectric.

There are very few candidates with k<2.

Amorphous BN (a-BN) is a promising candidate that is synthesized with a dielectric constant <2. However, as a-BN film thickness increases, the dielectric constant also increases, likely due to increased crystallization as the films thicken. Porosity could still be a problem for these systems.

Table 1 set forth below shows the dielectric constant and other properties for various materials as disclosed in S. Hong et al., Nature 582, 511 (2020).

TABLE 1

| | Dielectric | Density | Modulus | Hardness | Breakdown field | |
|---|---|---|---|---|---|---|
| | constant | (g/cm³) | (GPa) | (GPa) | (MV/cm) | |
| SiO₂ | 4 | 2.2 | 55-70 | 3.5 | >10 | Ref. [symbol] |
| FSG | 3.5-3.8 | 2.2 | −50 | 3.36 | >10 | Ref. [symbol] |
| (Fluorinated silicon glass) | | | | | | |
| OSG | [symbol] | [symbol] | 8.6-8.4 | 1.2-1.7 | 3.0 | Ref. [symbol] |
| (organosilicate glass or | | | | | Ref. [symbol] | |
| carbon-doped silicon glass) | | | | | | |
| HSQ | −3.0 | | | | | |
| MSQ | −2.5 | | 2.7-12.5 | [symbol] | 3.3 | Ref. [symbol] |
| | | | | | Ref. [symbol] | |
| Black Diamond (SiCOH) | 2.7-3.3 | [symbol] | 10-20 | [symbol] | 4.75 | Ref. [symbol] |
| | | | | | Ref. [symbol] | |
| Si_{w}CₓO_{y}H_{z} | 2.7-3.0 | | [symbol] | 1.3-2.4 | 6-10 | Ref. [symbol] |
| S [symbol] K | [symbol] | | 2.7 | 0.38 | 4 | Ref. [symbol] |
| SiCOH | [symbol] | 1.32 | 16.2 | 1.69 | | Ref. [symbol] |
| [symbol] SiCOH | 2.4 | 1.06 | 4.2 | [symbol] | | Ref. [symbol] |
| (pore <1.5 nm) | | | | | | |
| [symbol] SiCOH | 2.05 | [symbol] | 3.3 | [symbol] | | Ref. [symbol] |
| (pore <2.5 nm) | | | | | | |
| [symbol] -CH [symbol] | 2.2-2.3 | 0.92-0.94 | | | | Ref. [symbol] |
| Porous HSQ | 2.2 | 0.98 | | | | Ref. [symbol] |
| (hydrogen silsesquioxane) | | | | | | |
| (porosity 46%) | | | | | | |
| Porous MSQ | [symbol] | 0.89 | | | | Ref. [symbol] |
| (methylsilsesquioxane) | | | | | | |
| (porosity 34%) | | | | | | |
| BCN | 3.7-4.6 | | | | | Ref. [symbol] |
| (boron carbon nitride) | | | | | | |
| h-BN | 3.29-3.76 | 2.1 | 19.5-100 | [symbol] | | Ref. [symbol] |
| [symbol] -BN or | 2.2-2.4 | | | | | Ref. [symbol] |
| amorphous h-BN | 5.9 | | | | | Ref. [symbol] |
| [symbol] -BN | [symbol] | 2.1-2.3 | | | 7.3 | This [symbol] |

S. Hong et al., Nature 582, 511 (2020) [symbol]
indicates data missing or illegible when filed

Thus, there is a need for a transistor structure comprising a low-k spacer layer between metallic interconnects that overcomes the problems discussed above.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

The present disclosure is directed to a structure including an extension region which includes boron nitride nanotubes in a field-effect transistor (FET) to reduce the dielectric constant and therefore the RC-delay in the device. They can act as the spacer layer in any metallic interconnects to reduce the RC-delay.

The structure in this disclosure includes using single-walled or multi-walled BNNTs in any orientation (lateral, longitudinal or stacked) where the wrapping that is done is either zigzag or armchair direction, with or without any functionalized organic or inorganic groups. The dielectric constant can be lowered to below 2 by increasing the radius of the BNNT.

NTs with radii larger than 10 Å (also referred to as having a radius larger than 10 Å) with or without functionalized organic or inorganic groups can exhibit low-k behavior.

Also, 0D and 1D structures from existing 2D materials have been identified with a lower dielectric constant than their 2D counterparts.

A first embodiment of the present disclosure provides a structure comprising boron nitride nanotubes, wherein the structure (i) is an extension region in a field-effect transistor or (ii) comprises a metallic interconnect.

A second embodiment of the present disclosure provides a structure of the first embodiment, wherein the boron nitride nanotubes are single-walled boron nitride nanotubes.

A third embodiment of the present disclosure provides a structure of the first embodiment, wherein the boron nitride nanotubes are multi-walled boron nitride nanotubes.

A fourth embodiment of the present disclosure provides a structure of the first embodiment, wherein the boron nitride nanotubes are in a lateral orientation.

A fifth embodiment of the present disclosure provides a structure of the first embodiment, wherein the boron nitride nanotubes are in a longitudinal orientation.

A sixth embodiment of the present disclosure provides a structure of the first embodiment, wherein the boron nitride nanotubes are in a stacked orientation.

A seventh embodiment of the present disclosure provides a structure of the first embodiment, wherein the boron nitride nanotubes are wrapped in a zigzag direction.

An eighth embodiment of the present disclosure provides a structure of the first embodiment, wherein the boron nitride nanotubes are wrapped in an armchair direction.

A ninth embodiment of the present disclosure provides a structure of the first embodiment, wherein the boron nitride nanotubes have a radius larger than 10 Å.

A tenth embodiment of the present disclosure provides a structure of the ninth embodiment, wherein the boron nitride nanotubes have functionalized organic groups.

An eleventh embodiment of the present disclosure provides a structure of the ninth embodiment, wherein the boron nitride nanotubes have functionalized inorganic groups.

A twelfth embodiment of the present disclosure provides a structure of the ninth embodiment, wherein the boron nitride nanotubes do not have functionalized organic or inorganic groups.

A thirteenth embodiment of the present disclosure provides a structure of the first embodiment, wherein the structure is a 0D structure.

A fourteenth embodiment of the present disclosure provides a structure of the first embodiment, wherein the structure is a 1D structure.

A fifteenth embodiment of the present disclosure provides a structure of the first embodiment, wherein the boron nitride nanotubes have a diameter of from 10 to 100 Å.

A sixteenth embodiment of the present disclosure provides a structure of the first embodiment, wherein the boron nitride nanotubes have a diameter of about 30 Å.

A seventeenth embodiment of the present disclosure provides a structure of the first embodiment, wherein the boron nitride nanotubes have a dielectric constant <2.

An eighteenth embodiment of the present disclosure provides a structure of the first embodiment, wherein the boron nitride nanotubes have a dielectric constant of about 1.6.

A nineteenth embodiment of the present disclosure provides a transistor structure comprising a low-k spacer layer between metallic interconnects, wherein the low-k spacer layer comprises boron nitride nanotubes.

A twentieth embodiment of the present disclosure provides a method for reducing RC delay in an integrated circuit, comprising forming a component of the integrated circuit from boron nitride nanotubes.

### BRIEF DESCRIPTION OF DRAWINGS

Example embodiments of the present disclosure will be more clearly understood from the following detailed description taken in conjunction with the accompanying drawing in which:

FIG. 1 is a graph showing the relationship of transistor operation speed and interconnect delays.

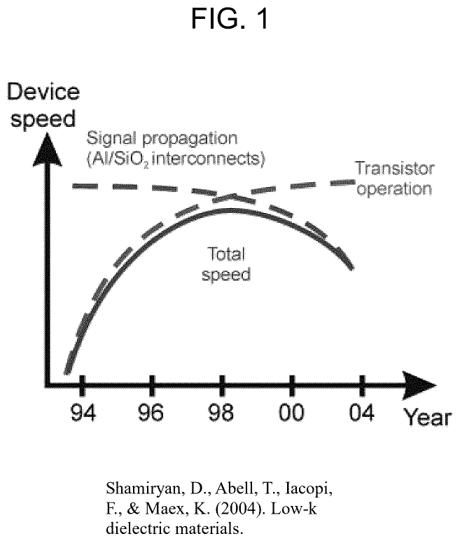

FIG. 2 is an illustration showing low-k dielectric spacers in a copper interconnect.

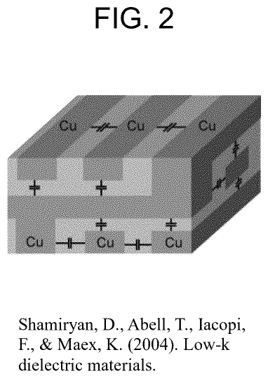

FIG. 3 is a plan view of an exemplary boron nitride nanotube.

FIG. 4 is a graph of nanotube diameter vs. DFT electronic dielectric constant.

FIG. 5 is a graph of in-plane lattice constant vs. DFT electronic dielectric constant.

FIG. 6 is a schematic of an exemplary structure including a dopant layer.

### DETAILED DESCRIPTION OF EXAMPLE EMBODIMENTS

The present disclosure is directed to using structures with boron nitride nanotubes (BNNTs) for low-k applications including as a spacer between metallic interconnects and in other circuits to minimize RC delay. While other variations of BN (a-BN) have been explored towards this, it is believed this is the first time BNNTs are explored as candidates for low-k applications.

By controlling the radius of the NT, the low-k can be controlled as well. The boron nitride nanotubes can be made part of other existing low-k materials, including a-BN.

Advantages of embodiments of the present disclosure include that the computed dielectric constant for BNNT can be about 1.6 for a NT with a typical diameter of about 30 Å (in the context of the present disclosure, the term “about” means±5%). This is already much lower than the existing low-k material SiCOH of 2.4 and also lower than the forecasted road map by IRDS.

While BNNT are commercially available, they are typically grown at temperatures above 900° C. Lowering the temperature of growth can be crucial for large scale applications. Some new reports suggest they can be grown around 600° C.

For zigzag and armchair NTs, the present disclosure has found that the dielectric constant (in-plane and out-of-plane) can be reduced by increasing the NT radius.

Including a BNNT in any orientation near the extension or spacer region can reduce the RC delay by reduced dielectric behavior.

BNNTs are easy to grow with CVD (scalable for device applications) with below 600° C. growth, and even are commercially available.

As indicated above, density can be tuned by changing the radius.

BNNTs have good chemical stability, are hard with very high elastic modulus (906 GPa, around 4 times the elastic modulus of steel) and Young's modulus (1 TPa), with tensile strength up to 30 GPa, and have high dielectric breakdown (8 MV/cm) and have wide band gaps.

A comparison of various properties of BNNT with other materials is shown in Table 2 below.

TABLE 2

| | Dielectric | Density | Modulus | Hardness | Breakdown field | |
|---|---|---|---|---|---|---|
| | constant | (g/cm³) | (GPa) | (GPa) | (MV/cm) | |
| SiO₂ | 4 | 2.2 | 55-70 | 3.5 | >10 | Ref. [symbol] |
| SiCOH | [symbol] | 1.32 | [symbol] | [symbol] | | Ref. [symbol] |
| pSiCOH | 2.4 | 1.06 | 4.2 | [symbol] | | Ref. [symbol] |
| (pore <1.5 nm) | | | | | | |
| pSiCOH | 2.05 | 0.87 | 3.3 | [symbol] | | Ref. [symbol] |
| (pore <2.5 nm) | | | | | | |
| h-BN | 3.29-3.76 | 2.1 | 19.5-100 | [symbol] | | Ref. [symbol] |
| [symbol] -BN or | 2.2-2.4 | | | | | Ref. [symbol] |
| amorphous h-BN | 5.9 | | | | | Ref. [symbol] |
| [symbol] -BN | [symbol] | 2.1-2.3 | | | 7.3 | |
| BNNT | <2 | <2.1 | 1000 | 24-76 | 8 | |

S. Hong et al., Nature 582, 511 (2020), except for BNNT [symbol]
indicates data missing or illegible when filed

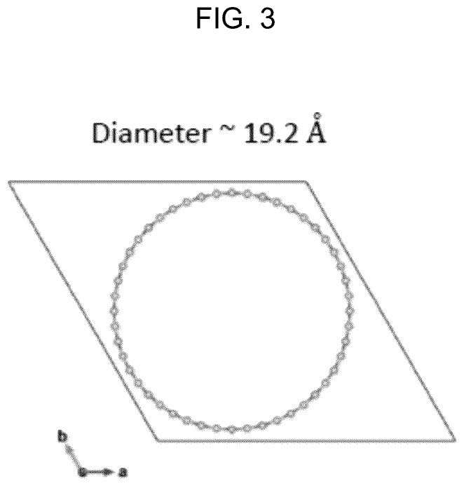

A plan view of an exemplary boron nitride nanotube is shown in FIG. 3, in which the boron nitride nanotube has a diameter of ˜19.2 Å.

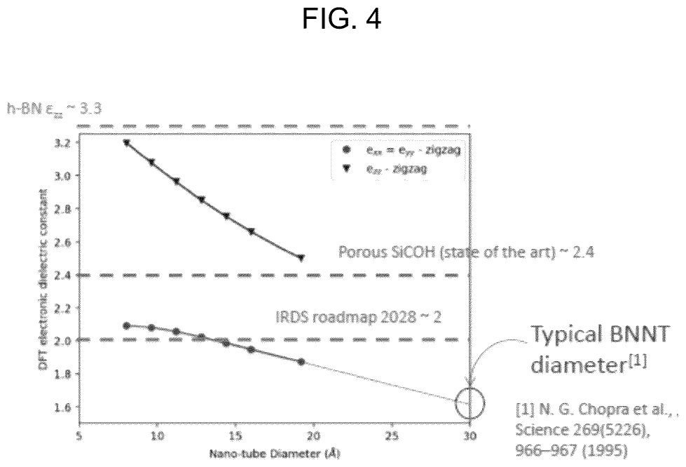

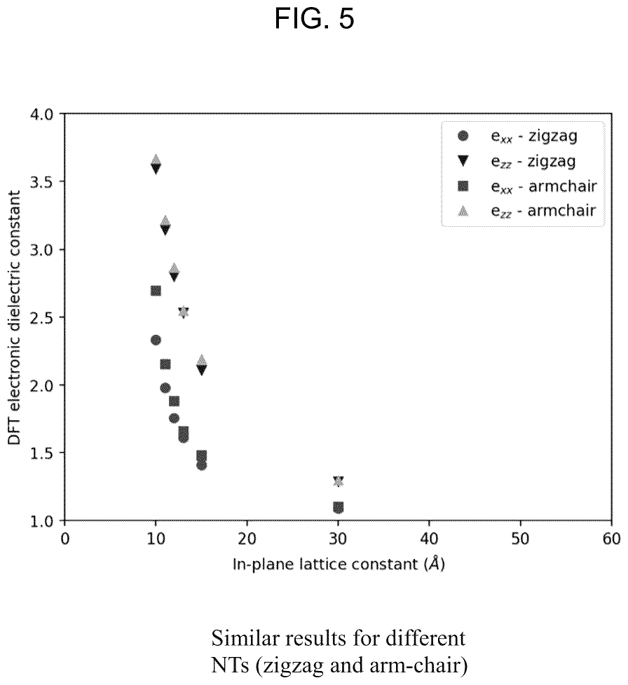

A graph of nanotube diameter vs. DFT electronic dielectric constant is set forth in FIG. 4, and a graph of in-plane lattice constant vs. DFT electronic dielectric constant is set forth in FIG. 5.

Further, the total energies and dielectric constant for zigzag NT (8,0) and armchair (5,5) NTs with different inter-tube distances were computed, and the results show that irrespective of the NT termination, electronic dielectric constant can be <2.

Also, the larger the tube-diameter, the smaller the dielectric constant. This statement is true for both in-plane radial (perpendicular to the tube-diameter) and out-of-plane axial (along the tube diameter) dielectric constants (the effect is more prominent in the latter). As the inter-tube distance is kept fixed at ˜5 Å, this clearly shows the inverse correlation of dielectric constant and tube-diameter. By interpolation, the in-plane dielectric constant is estimated to be ˜1.6 for a diameter of ˜30 Å (Exp. Diameters can range from 10 to 100 Å; the original synthesis of BNNT in 1995 had a distribution from 10-30 Å).

Similar results were obtained with the arm-chair direction as well. The result shows a robust way to make the dielectric constant to be less than 2 (and even ˜1.5) by increasing the NT radius.

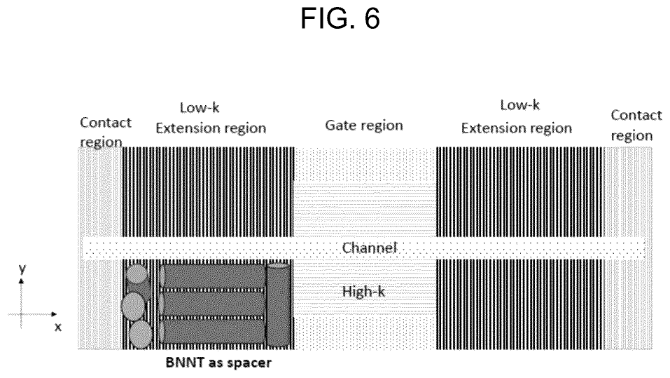

A schematic of an exemplary structure of the present disclosure including a dopant layer is shown in FIG. 6. More particularly, a schematic of the top view of the different regions in a typical FET (e.g., slice of a Gate All Around (GAA) FET), wherein nanotubes occupy the low-k spacer extension region and can be oriented in any relative direction, is shown in FIG. 6.

The foregoing is illustrative of exemplary embodiments and is not to be construed as limiting the disclosure. Although a few exemplary embodiments have been described, those skilled in the art will readily appreciate that many modifications are possible in the above embodiments without materially departing from the disclosure.

What is claimed is:

1. A structure comprising boron nitride nanotubes, wherein the structure (i) is an extension region in a field-effect transistor or (ii) comprises a metallic interconnect.

2. The structure of claim 1, wherein the boron nitride nanotubes are single-walled boron nitride nanotubes.

3. The structure of claim 1, wherein the boron nitride nanotubes are multi-walled boron nitride nanotubes.

4. The structure of claim 1, wherein the boron nitride nanotubes are in a lateral orientation.

5. The structure of claim 1, wherein the boron nitride nanotubes are in a longitudinal orientation.

6. The structure of claim 1, wherein the boron nitride nanotubes are in a stacked orientation.

7. The structure of claim 1, wherein the boron nitride nanotubes are wrapped in a zigzag direction.

8. The structure of claim 1, wherein the boron nitride nanotubes are wrapped in an armchair direction.

9. The structure of claim 1, wherein the boron nitride nanotubes have a radius larger than 10 Å.

10. The structure of claim 9, wherein the boron nitride nanotubes have functionalized organic groups.

11. The structure of claim 9, wherein the boron nitride nanotubes have functionalized inorganic groups.

12. The structure of claim 9, wherein the boron nitride nanotubes do not have functionalized organic or inorganic groups.

13. The structure of claim 1, wherein the structure is a 0D structure.

14. The structure of claim 1, wherein the structure is a 1D structure.

15. The structure of claim 1, wherein the boron nitride nanotubes have a diameter of from 10 to 100 Å.

16. The structure of claim 1, wherein the boron nitride nanotubes have a diameter of about 30 Å.

17. The structure of claim 1, wherein the boron nitride nanotubes have a dielectric constant <2.

18. The structure of claim 1, wherein the boron nitride nanotubes have a dielectric constant of about 1.6.

19. A transistor structure comprising a low-k spacer layer between metallic interconnects, wherein the low-k spacer layer comprises boron nitride nanotubes.

20. A method for reducing RC delay in an integrated circuit, comprising forming a component of the integrated circuit from boron nitride nanotubes.
